(19) United States
(12) Patent Application Publication
(10) Pub. No.: US 2011/0205310 A1
(43) Pub. Date: Aug. 25, 2011

(54) PIEZOELECTRIC DEVICE, LIQUID EJECTING HEAD, AND LIQUID EJECTING APPARATUS

(75) Inventor: Eiji Osawa, Chino-shi (JP)

(73) Assignee: SEIKO EPSON CORPORATION, Shinjuku-ku (JP)

(21) Appl. No.: 13/033,494

(22) Filed: Feb. 23, 2011

(30) Foreign Application Priority Data
Feb. 25, 2010 (JP) 2010-040792

(51) Int. Cl. B41J 2/045; H01L 41/04

(52) U.S. Cl. 347/68; 310/311

(57) ABSTRACT

A piezoelectric device comprises a first electrode, a piezoelectric layer above the first electrode, a metal oxide film including a lanthanum nickel oxide above the piezoelectric layer, and a second electrode above the metal oxide film. The metal oxide film has a perovskite structure and a lanthanum/nickel molar ratio of 1.2 to 1.5.

### CROSS-REFERENCE TO RELATED APPLICATIONS

This application claims the benefit of priority to Japanese Patent Application No. 2010-040792 filed Feb. 25, 2010, the contents of which are hereby incorporated by reference in their entirety.

### BACKGROUND

1. Technical Field

The present invention relates to a piezoelectric device that includes a piezoelectric layer and electrodes on both sides of the piezoelectric layer, a liquid ejecting head, and a liquid ejecting apparatus.

2. Related Art

A type of liquid ejecting head currently available is an ink jet recording head in which part of a pressure-generating chamber communicating with nozzle openings for ejecting ink droplets is constituted by a diaphragm. The diaphragm is deformed by a pressure-generating unit to pressurize the ink contained in the pressure-generating chamber so that ink droplets can be ejected from the nozzle openings.

A piezoelectric device including a piezoelectric film composed of a piezoelectric material having an electromechanical transducer function and two electrodes sandwiching the piezoelectric film is used as the pressure-generating unit (e.g., refer to Japanese Unexamined Patent Application Publication No. 2000-326503).

There are two types of ink jet recording heads put into practical use. One is those which use longitudinal vibration-mode actuators that extend and contract in the axis direction of the piezoelectric device and the other is those which use flexural-vibration-mode actuators. These actuators require piezoelectric devices that can create large strains with low driving voltage, i.e., piezoelectric devices with large displacements, in order to achieve high density.

However, according to the piezoelectric device disclosed in Japanese Unexamined Patent Application Publication No. 2000-326503, a lanthanum nickel oxide is contained in a first conductive layer, which is the electrode on the lower side of the piezoelectric layer. There has been a problem a decrease in the effective electric field applied to the piezoelectric device and degradation of piezoelectric characteristics depending on the thickness.

Such disadvantages are not unique to ink jet recording heads that eject inks but other liquid discharging heads that eject liquid other than inks have the same disadvantages.

### SUMMARY

An advantage of some aspects of the invention is to provide a piezoelectric device with improved piezoelectric characteristics, a liquid ejecting head, and a liquid ejecting apparatus.

A first aspect of the invention provides a piezoelectric device that includes a first electrode, a piezoelectric layer on the first electrode, a metal oxide film on the piezoelectric layer, and a second electrode on the metal oxide film. The metal oxide film is composed of a lanthanum nickel oxide having a perovskite structure and a lanthanum/nickel molar ratio of 1.2 to 1.5. The first aspect provides a piezoelectric device having a saturation polarization that barely drops by repeated driving, voltage resistance, and a large displacement.

Preferably, the metal oxide film has a thickness of 1 nm or more to prevent formation of a damaged layer at the interface between the piezoelectric layer and the second electrode during forming the second electrode on the piezoelectric material layer.

Preferably, the first electrode is mainly composed of platinum or iridium. A first electrode mainly composed of platinum or iridium has high electrical conductivity and the thickness thereof is easy to control. The thickness of the first electrode affects the resonance frequency of the piezoelectric device. Thus, the resonance frequency of the piezoelectric can be easily controlled since the thickness of the first electrode is easy to control.

A second aspect of the invention provides a liquid ejecting head that includes the piezoelectric device described above, the piezoelectric device serving as a pressure-generating unit that changes a pressure of a pressure-generating chamber in communication with a nozzle opening through which liquid is ejected. According to this aspect, the decrease in displacement caused by repeated driving of the piezoelectric device can be suppressed and a liquid ejecting head with a longer lifetime can be provided.

A third aspect of the invention provides a liquid ejecting apparatus including the liquid ejecting head described above. According to this aspect, a liquid ejecting apparatus having a longer lifetime and improved long-term reliability can be provided.

### BRIEF DESCRIPTION OF THE DRAWINGS

The invention will be described with reference to the accompanying drawings, wherein like numbers reference like elements.

FIG. 1 is an exploded perspective view showing a schematic structure of an ink jet recording head according to an embodiment of the invention.

FIG. 2A is a plan view of the recording head and FIG. 2B is a cross-sectional view of the recording head.

FIG. 3 is an enlarged cross-sectional view of a relevant part of the recording head.

FIGS. 4A to 4C are cross-sectional view showing a method for producing the recording head.

FIGS. 5A to 5F are cross-sectional view showing a method for producing the recording head.

FIGS. 6A and 6B are cross-sectional view showing a method for producing the recording head.

FIGS. 7A and 7B are cross-sectional view showing a method for producing the recording head.

FIGS. 8A and 8B are cross-sectional view showing a method for producing the recording head.

FIG. 9 is a graph showing results of measurement of saturation polarization of each piezoelectric device.

FIG. 10 is a graph showing results of measurement of breakdown voltage of each piezoelectric device.

FIG. 11 is a graph showing results of measurement of displacement of each piezoelectric device.

FIG. 12 is a graph showing the relationship between lanthanum/nickel molar ratio and the lattice constant.

FIG. 13 is a diagram showing a schematic structure of a recording apparatus according to an embodiment.

### DESCRIPTION OF EXEMPLARY EMBODIMENTS

The invention will now be described in detail by using embodiments.

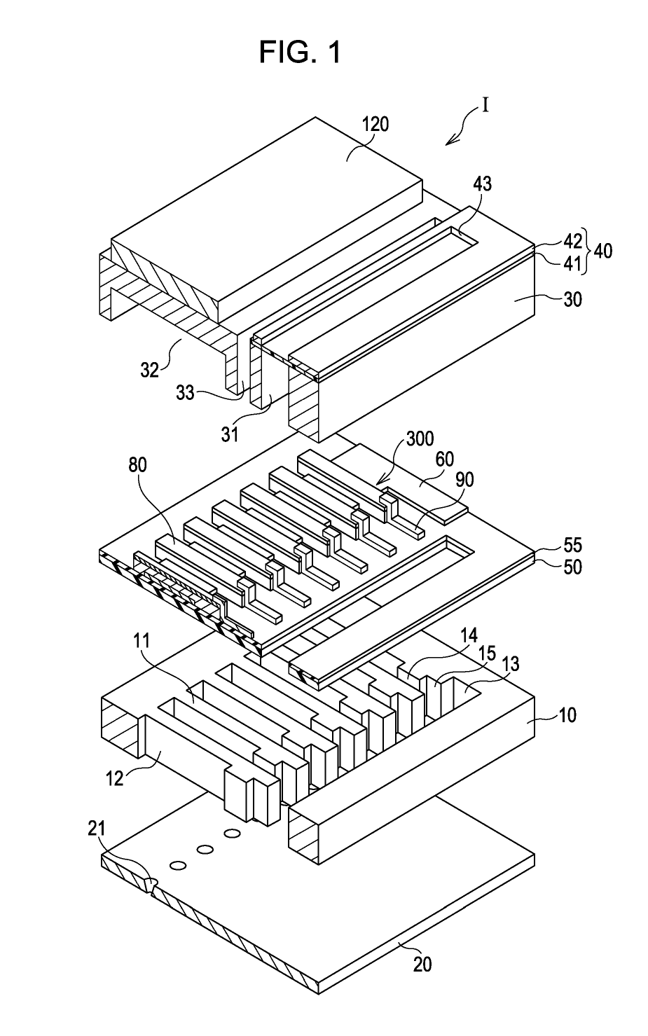

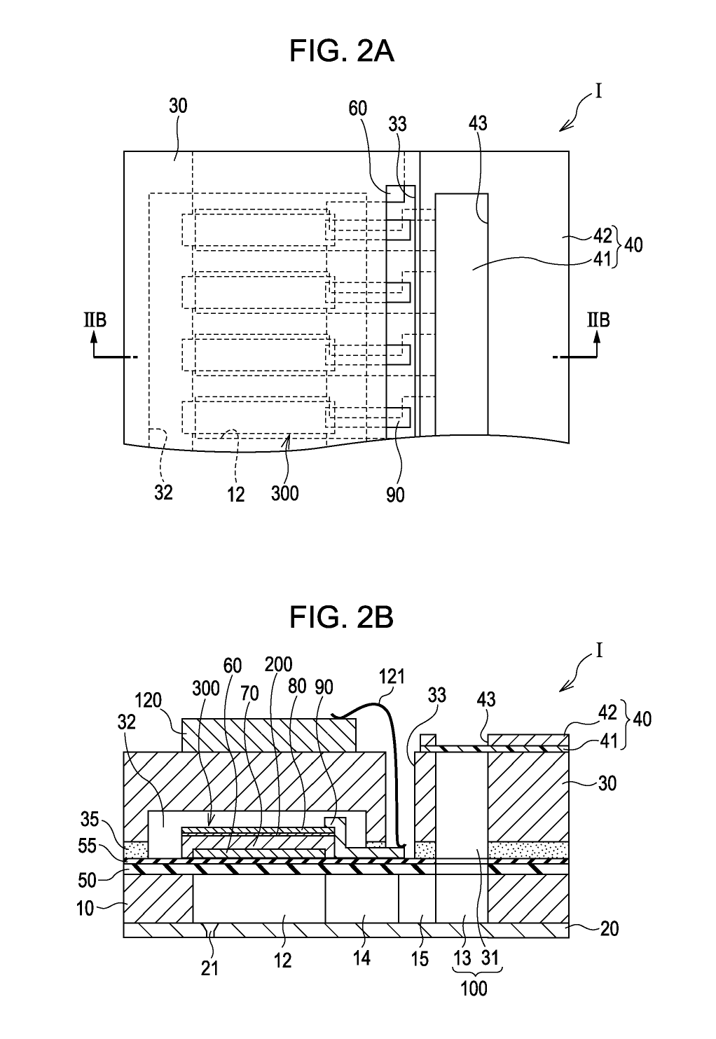

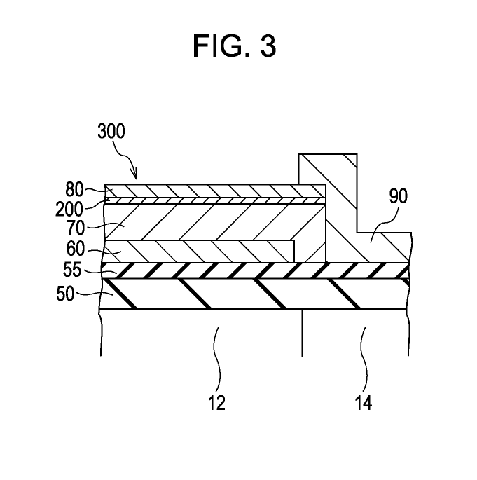

FIG. 1 is an exploded perspective view showing a schematic structure of an ink jet recording head which is one example of the liquid ejecting head according to an embodiment of the invention. FIG. 2A is a plan view of the ink jet recording head shown in FIG. 1. FIG. 2B is a cross-sectional view of the in jet recording head taken along line IIB-IIB of FIG. 2A. FIG. 3 is an enlarged cross-sectional view of a relevant part from FIGS. 2A and 2B.

In this embodiment, a channel forming substrate 10 is a silicon single crystal substrate. An elastic film 50 composed of silicon dioxide is formed on one surface of the channel forming substrate 10. A plurality of pressure-generating chambers 12 that extend in the width direction of the channel forming substrate 10 are aligned side by side. A communicating section 13 is also formed in the channel forming substrate 10. The communicating section 13 is formed in a region on the outer side in the longitudinal direction of the pressure-generating chambers 12. The communicating section 13 is in communication with the pressure-generating chambers 12 via ink channels 14 and communication channels 15. One ink channel 14 and one communication channel 15 are provided for every pressure-generating chamber 12. The communicating section 13 is in communication with a reservoir section 31 of a protective substrate described below and thereby forms part of the reservoir that serves as a common ink chamber for the pressure-generating chambers 12. The ink channels 14 have a width smaller than that of the pressure-generating chambers 12 to keep constant the channel resistance of the ink flowing from the communicating section 13 into the pressure-generating chambers 12. In this embodiment, the ink channels 14 are formed by decreasing the width of the channels from one side. Alternatively, the ink channels 14 may be formed by decreasing the width of the channels from both sides. Yet alternatively, the ink channels 14 may be formed by narrowing the channels in the thickness direction instead of decreasing the width of the channels. In sum, a liquid channel constituted by the pressure-generating chambers 12, the communicating section 13, the ink channels 14, and the communication channels 15 is formed in the channel forming substrate 10 according to this embodiment.

A nozzle plate 20 having nozzle openings 21 is fixed on an opening-side surface of the channel forming substrate 10. The nozzle openings 21 are in communication with the vicinities of the ends of the pressure-generating chambers 12 that are remote from the ink channels 14. The nozzle plate 20 is composed of, for example, glass ceramic, silicon single crystals, or stainless steel.

The elastic film 50 is formed on the surface of the channel forming substrate 10 opposite the opening-side surface as described above, and an insulator film 55 is formed on the elastic film 50. A first electrode 60, a piezoelectric layer 70, a metal oxide film 200, and a second electrode 80 are stacked on the insulator film 55 through a process described below to form a piezoelectric device 300. The piezoelectric device 300 is the section that includes the first electrode 60, the piezoelectric layer 70, the metal oxide film 200, and the second electrode 80. In general, one of the electrodes of the piezoelectric device 300 is formed as a common electrode, and the other electrode and the piezoelectric layer 70 are formed by patterning for every pressure-generating chamber 12. In this embodiment, the first electrode 60 is formed as a common electrode of the piezoelectric device 300, and the second electrode 80 is formed as an individual electrode of the piezoelectric device 300. However, this arrangement may be reversed depending on the convenience of the driving circuit and wiring. A device having a piezoelectric device 300 displaceably formed is referred to as an “actuator”. In this embodiment, an actuator including a piezoelectric device 300 displaceably formed is provided as a pressure-generating unit that changes the pressure inside the pressure-generating chamber 12. In the example described above, the elastic film 50, the insulator film 55, and the first electrode 60 act as a diaphragm. However, the arrangement is not limited to this. For example, only the first electrode 60 may be configured act as a diaphragm without forming the elastic film 50 and the insulator film 55. Alternatively, the piezoelectric device 300 may be configured to substantially serve as a diaphragm.

The first electrode 60 may be composed of any material selected from electrically conductive metals, alloys, and metal oxides. In this embodiment, the first electrode 60 is mainly composed of platinum or iridium. A first electrode 60 mainly composed of platinum or iridium has high electrical conductivity and the thickness of the film can be easily controlled. The thickness of the first electrode 60 affects the resonance frequency of the piezoelectric device 300 described above. Thus, the resonance frequency of the piezoelectric device 300 can be easily adjusted by controlling the thickness of the first electrode 60. It should be noted here that controlling the thickness of such a first electrode 60 is easier than controlling the thickness of a first electrode composed of a lanthanum nickel oxide. Accordingly, the resonance frequency of the piezoelectric device 300 including such a first electrode 60 is easier than controlling the resonance frequency of a piezoelectric device having a first electrode composed of a lanthanum nickel oxide.

The piezoelectric layer 70 is formed on the first electrode 60 and is composed of a piezoelectric material that has an electromechanical transducer function, in particular, a ferroelectric material having a perovskite crystal structure and containing Pb, Zr, and Ti as metals. The material for the piezoelectric layer 70 is preferably a ferroelectric material such as lead zirconate titanate (PZT) or a ferroelectric material to which a metal oxide such as niobium oxide, nickel oxide, or magnesium oxide is added, for example. Specific examples of such a material include lead zirconate titanate (Pb(Zr,Ti)O₃), lead lanthanum zirconate titanate ((Pb,La)(Zr,Ti)O₃), and lead zirconium titanate magnesium niobate ((Pb(Zr,Ti)(Mg,Nb)O₃).

The piezoelectric layer 70 may have any of the (100), (110), and (111) preferred orientations and any crystal structure selected from a rhombohedral system, a tetragonal system, and monoclinic system. The piezoelectric layer 70 of this embodiment has a (100) preferred orientation. A piezoelectric layer 70 having a (100) preferred orientation can create a large displacement with a low driving voltage, i.e., has good displacement characteristics, and thus is suitable for use in an ink jet recording head I. The piezoelectric layer 70 may be caused to have the (100) or (110) preferred orientation by forming an orientation controlling layer, which has a particular crystal orientation, under or above the first electrode 60, or by forming a crystal seed layer on the first electrode 60, the crystal seed layer being composed of titanium or the like that cancels the orientation of the first electrode 60 and then adjusting the heat treatment temperature or the like for forming the piezoelectric layer 70. It should be noted that the meaning of the phrase “crystals have a (100) preferred orientation” includes the instances where all of the crystals are oriented in the (100) face and instances where most (e.g., 90% or more) of crystals are oriented in the (100) face.

The thickness of the piezoelectric layer 70 is small enough to prevent cracking during the production process but is large enough to exhibit sufficient displacement characteristics. For example, the piezoelectric layer 70 of this embodiment is formed to have a thickness of about 0.5 to 5 μm.

A metal oxide film 200 composed of lanthanum nickel oxide (LNO) is formed on the piezoelectric layer 70 (on the opposite side of the first electrode 60). A second electrode 80 having high electrical conductivity composed of, for example, iridium (Ir) is formed on the metal oxide film 200.

The metal oxide film 200 is composed of a lanthanum nickel oxide having a perovskite structure and a lanthanum/nickel molar ratio of 1.2 to 1.5. Although the details are provided below, a piezoelectric device 300 having good displacement characteristics and improved voltage resistance can be provided by disposing such a metal oxide film 200 between the piezoelectric layer 70 and the second electrode 80.

The thickness of the metal oxide film 200 is preferably 1 nm or more. When the second electrode 80 is formed by sputtering without forming the metal oxide film 200, a layer (damaged layer) in which iridium and lead zirconate titanate or the like are mixed is formed at the interface between the piezoelectric layer 70 and the second electrode 80. This formation of the damaged layer can be suppressed by forming a metal oxide film 200 having a thickness of 1 nm or more.

Since the metal oxide film 200 has electrical conductivity, it substantially functions as an electrode (second electrode) through which a voltage is applied to the piezoelectric layer 70.

The second electrode 80 is connected with a lead electrode 90 composed of, for example, gold. The lead electrode 90 extends from the vicinity of the ink channel 14-side end of the second electrode 80 to above the insulator film 55.

Referring to FIGS. 1 and 2, a protective substrate 30 having the reservoir section 31 constituting at least part of a reservoir 100 is bonded with an adhesive 35 to the channel forming substrate 10 on which the piezoelectric devices 300 are formed, i.e., on the first electrode 60, the insulator film 55, and the lead electrode 90. The reservoir section 31 of this embodiment penetrates the protective substrate 30 in the thickness direction and extends in the width direction of the pressure-generating chambers 12. As described above, the reservoir section 31 is in communication with the communicating section 13 of the channel forming substrate 10 and constitutes the reservoir 100 serving as a common ink chamber for the pressure-generating chambers 12. Alternatively, the communicating section 13 of the channel forming substrate 10 may be divided into a plurality of subsections corresponding to the pressure-generating chambers 12, and only the reservoir section 31 may be used as the reservoir. Alternatively, for example, only the pressure-generating chambers 12 may be formed in the channel forming substrate 10, and the reservoir 100 and the ink channels 14 in communication with the pressure-generating chambers 12 may be formed in a member (e.g., elastic film 50 or insulator film 55) interposed between the channel forming substrate 10 and the protective substrate 30.

A piezoelectric device holder 32 having a space that does not obstruct the motion of the piezoelectric device 300 is provided in the protective substrate 30 in a region opposing the piezoelectric devices 300. The piezoelectric device holder 32 should have a space that does not obstruct the motion of the piezoelectric device 300 and may be sealed or unsealed.

The protective substrate 30 is preferably composed of a material having a coefficient of thermal expansion substantially equal to that of the channel forming substrate 10, e.g., glass or ceramic. The protective substrate 30 of this embodiment is composed of the same silicon single crystals as that of the channel forming substrate 10.

A penetrating hole 33 that penetrates the protective substrate 30 in the thickness direction is formed in the protective substrate 30. Ends of the lead electrodes 90 extending from the respective piezoelectric devices 300 are exposed in the penetrating hole 33.

A driving circuit 120 for driving the piezoelectric devices 300 arranged side by side is fixed on the protective substrate 30. For example, a circuit substrate, a semiconductor integrated circuit (IC), or the like may be used as the driving circuit 120. The driving circuit 120 is electrically coupled with each lead electrode 90 through a connecting wiring 121 formed of conductive wires such as bonding wires.

A compliance substrate 40 constituted by a sealing film 41 and a fixing plate 42 is bonded to the protective substrate 30. The sealing film 41 is composed of a material that has flexibility and low stiffness. The sealing film 41 seals one of the surfaces of the reservoir section 31. The fixing plate 42 is composed of a relatively hard material. The region of the fixing plate 42 opposing the reservoir 100 is formed as an opening 43 by completely removing the material in the thickness direction. Thus, one of the surfaces of the reservoir 100 is sealed by the flexible sealing film 41 only.

According to the ink jet recording head of this embodiment, an ink is taken in from the ink inlet connected to an external ink supply unit (not shown) to fill the interior of the components from the reservoir 100 to the nozzle openings 21, and a voltage is applied between the first electrodes 60 corresponding to the pressure-generating chambers 12 and the second electrode 80 in response to a recording signal fed from the driving circuit 120. As a result, the elastic film 50, the insulator film 55, the first electrodes 60, and the piezoelectric layer 70 undergo flexural deformation and the pressure inside the pressure-generating chambers 12 is increased, thereby ejecting ink droplets from the nozzle openings 21.

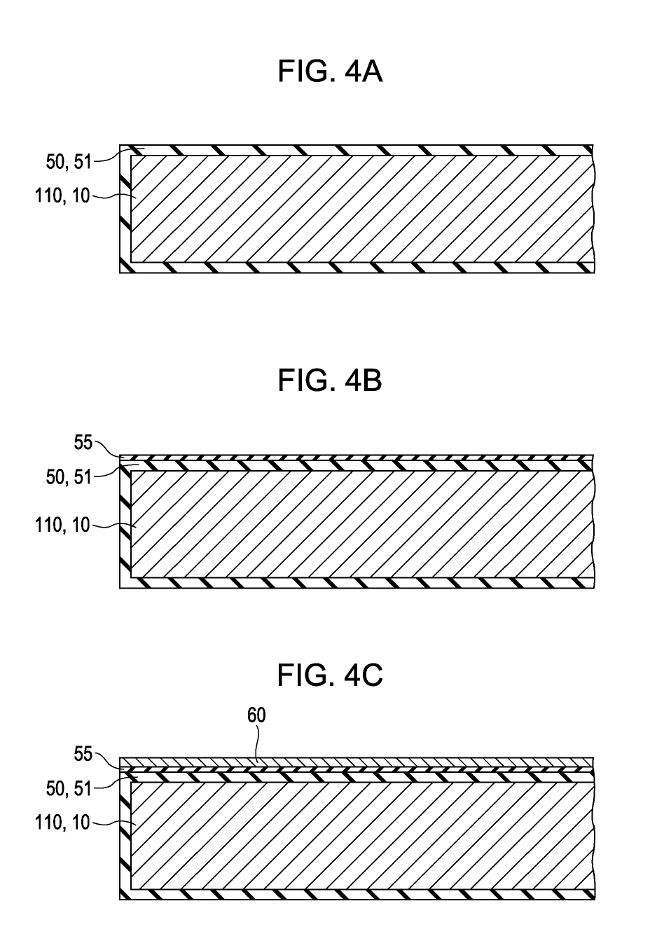

A method for producing such an ink jet recording head will now be described with reference to FIGS. 4A to 8B. FIGS. 4A to 8B are cross-sectional views taken in the longitudinal direction of the pressure-generating chambers 12, showing a method for producing an ink jet recording head which is one example of the liquid ejecting head according to an embodiment of the invention. Although description is given by using an example in which lead zirconate titanate is used to form the piezoelectric layer 70, the material is not limited to this and any other suitable piezoelectric material may be used.

First, as shown in FIG. 4A, an oxide film 51 that forms the elastic film 50 is formed on a silicon wafer 110. The wafer 110 is a wafer on which a plurality of channel forming substrates 10 are integrally formed.

Then, as shown in FIG. 4B, an insulator film 55 composed of an oxide material different from that of the elastic film 50 is formed on the elastic film 50 (oxide film 51).

Next, as shown in FIG. 4C, a first electrode 60 is formed on the entire surface of the insulator film 55. The material for the first electrode 60 is not particularly limited. When lead zirconate titanate (PZT) is used in the piezoelectric layer 70, a material having conductivity not much affected by diffusion of the lead oxide is preferably used. Examples of the material for the first electrode 60 include platinum and iridium. The first electrode 60 may be formed by sputtering or physical vapor deposition (PVD), for example.

Next, a piezoelectric layer 70 composed of lead zirconate titanate (PZT) is formed. In this embodiment, a sol-gel method is used to form the piezoelectric layer 70. The method for forming the piezoelectric layer 70 is not limited to the sol-gel method. A metal-organic decomposition (MOD) method may be employed, for example.

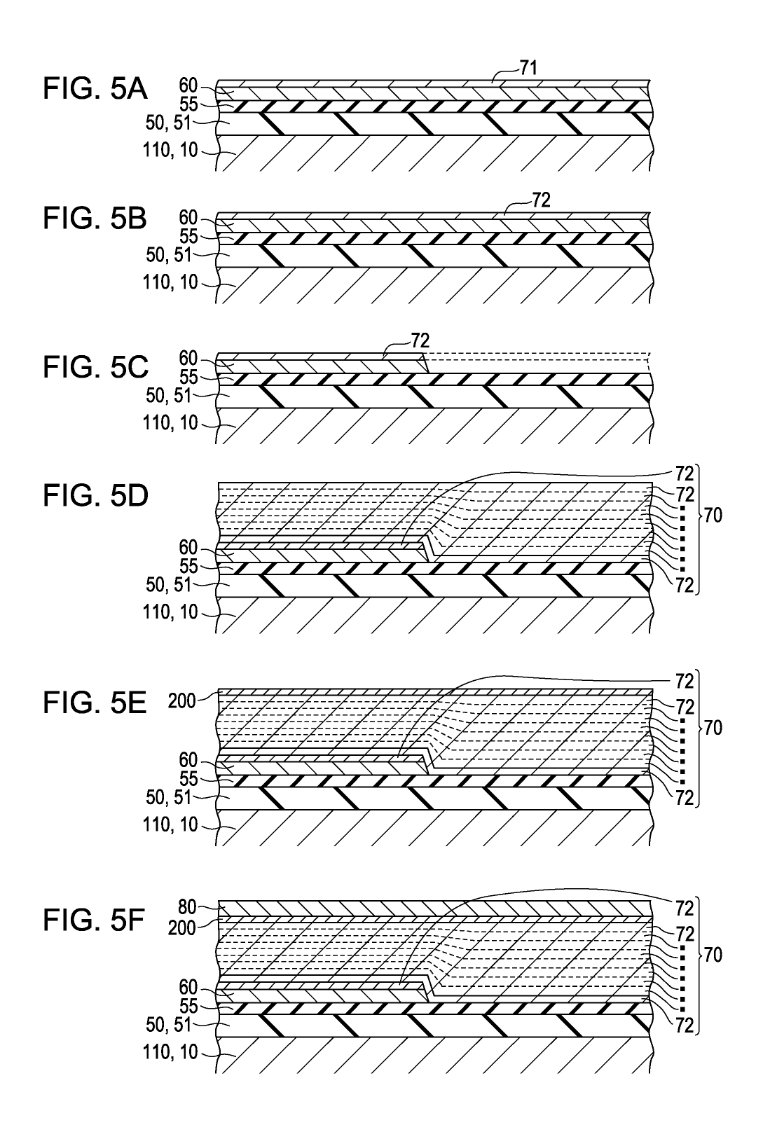

Specific procedures for forming the piezoelectric layer 70 will now be described. First, as shown in FIG. 5A, a piezoelectric precursor film 71, which is a PZT precursor film, is formed on the first electrode 60. That is, a sol (solution) containing a metal organic compound is applied on the wafer 110 on which the first electrode 60 has been formed (coating step).

Next, the piezoelectric precursor film 71 is heated to a particular temperature and dried for a particular length of time (drying step). For example, in the drying step of this embodiment, the sol coating the wafer 110 is dried by retaining a temperature of 150° C. to 170° C. for 3 to 30 minutes.

Next, the dried piezoelectric precursor film 71 is heated to a particular temperature and retained thereat for a particular length of time to be degreased (degreasing step). In this embodiment, the dried piezoelectric precursor film 71 is heated to 300° C. to 400° C. and retained thereat for 3 to 30 minutes to conduct degreasing. The meaning of the term “degreasing” is to cause organic components contained in the piezoelectric precursor film 71 to separate by converting them into NO₂, CO₂, H₂O, etc, and to form a piezoelectric precursor film 71 that is not crystallized, i.e., that is amorphous.

Next, as shown in FIG. 5B, the piezoelectric precursor film 71 is heated to a particular temperature and retained thereat for a particular length of time to be crystallized and to thereby form a piezoelectric film 72 (baking step). In this embodiment, the degreased piezoelectric precursor film 71 is preferably baked by heating the film to 500° C. to 800° C.

Next, as shown in FIG. 5C, after forming the first layer of the piezoelectric film 72 on the first electrode 60, the first electrode 60 and the first layer of the piezoelectric film 72 are simultaneously patterned to form sloped side surfaces. Patterning of the first electrode 60 and the first layer of the piezoelectric film 72 can be conducted by dry etching, e.g., ion milling.

If the first layer of the piezoelectric film 72 is formed after patterning of the first electrode 60, the surface of the first electrode 60 and the crystal seed layer (not shown) such as titanium on the surface are modified due to the photographic process, ion milling, and ashing conducted for patterning the first electrode 60. If a piezoelectric film 72 is formed on the modified surfaces, the crystallinity of the piezoelectric film 72 becomes unsatisfactory, and the growth of second and subsequent layers of piezoelectric films 72 is also affected by the conditions of the crystals of the first layer of the piezoelectric film 72. As a result, a piezoelectric layer 70 having good crystallinity cannot be formed.

In comparison, if the first layer of the piezoelectric film 72 and the first electrode 60 are patterned simultaneously after formation of the first layer of the piezoelectric film 72, the first layer of the piezoelectric film 72 has favorable characteristics as a seed layer for satisfactorily growing crystals, i.e., second and subsequent layers of piezoelectric films 72, when compared with other crystal seeds such as titanium. Thus, crystal growth for the second and subsequent layers of piezoelectric films 72 is not greatly affected despite formation of an extremely thin modified layer on the surface by the patterning.

As shown in FIG. 5D, a piezoelectric layer 70 including two or more stacked piezoelectric films 72 can be formed by repeating at least twice the precursor film-forming process (coating step, drying step, and degreasing step) and the piezoelectric film forming process including the baking step.

Next, as shown in FIG. 5E, a metal oxide film 200 composed of lanthanum nickel oxide is formed on the piezoelectric layer 70. The metal oxide film 200 may be formed by a sol-gel method, a sputtering method, or a physical vapor deposition (PVD) method, for example.

An oxygen deficient layer in which oxygen is deficient compared to other regions is formed on the uppermost surface of the piezoelectric layer 70 because the process of forming the piezoelectric film 72 is repeated. However, since formation of the metal oxide film 200 is conducted in an oxygen atmosphere, oxygen is introduced into the oxygen deficient layer. In other words, formation of the oxygen deficient layer can be suppressed by forming the metal oxide film 200.

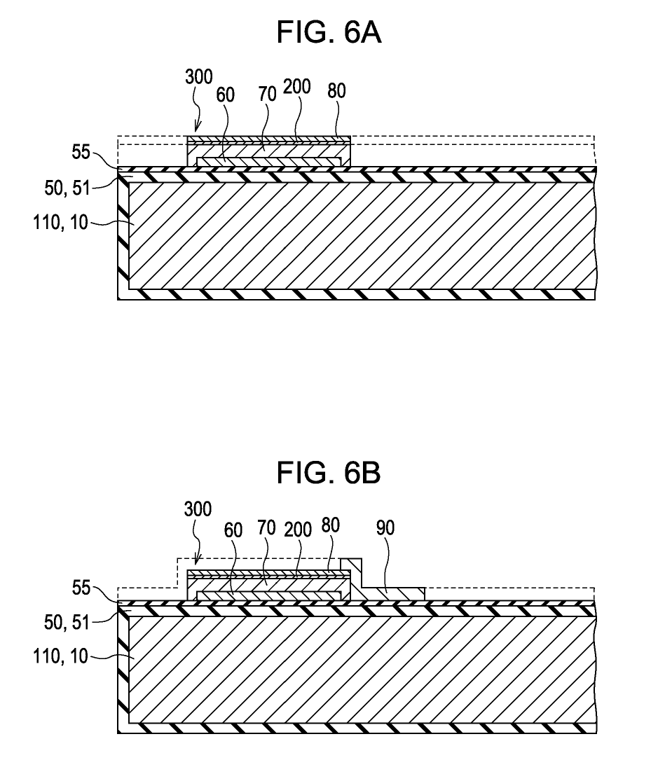

Next, as shown in FIG. 5F, a second electrode 80 composed of iridium (Ir) is formed over the metal oxide film 200. Then, as shown in FIG. 6A, the piezoelectric layer 70, the metal oxide film 200, and the second electrode 80 are patterned in the region opposing the pressure-generating chambers 12 to form a piezoelectric device 300. Examples of the method for patterning the piezoelectric layer 70, the metal oxide film 200, and the second electrode 80 include dry etching processes such as reactive ion etching and ion milling.

Next, a lead electrode 90 is formed. In particular, as shown in FIG. 6B, a lead electrode 90 composed of gold (Au) is formed on the entire surface of a wafer 110 for forming channel-forming substrates, and then the lead electrode 90 is patterned via a mask pattern (not shown) composed of resist or the like to form electrodes corresponding to the piezoelectric devices 300.

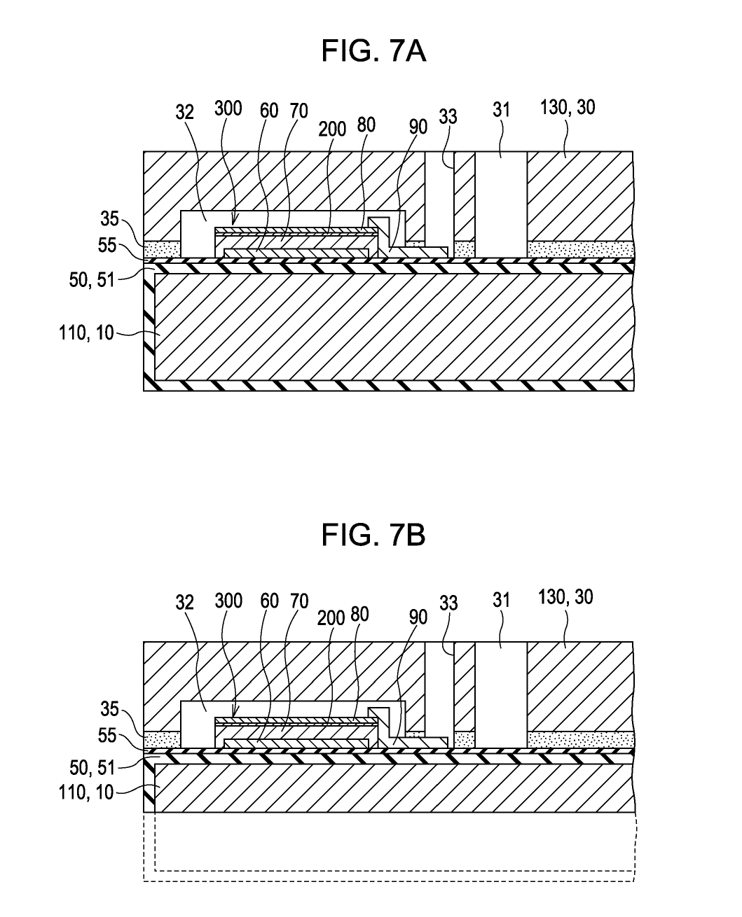

Next, as shown in FIG. 7A, a silicon wafer 130 for forming protective substrates 30 is bonded onto the piezoelectric device 300-side of the wafer 110. Then as shown in FIG. 7B, the wafer 110 is thinned to a particular thickness.

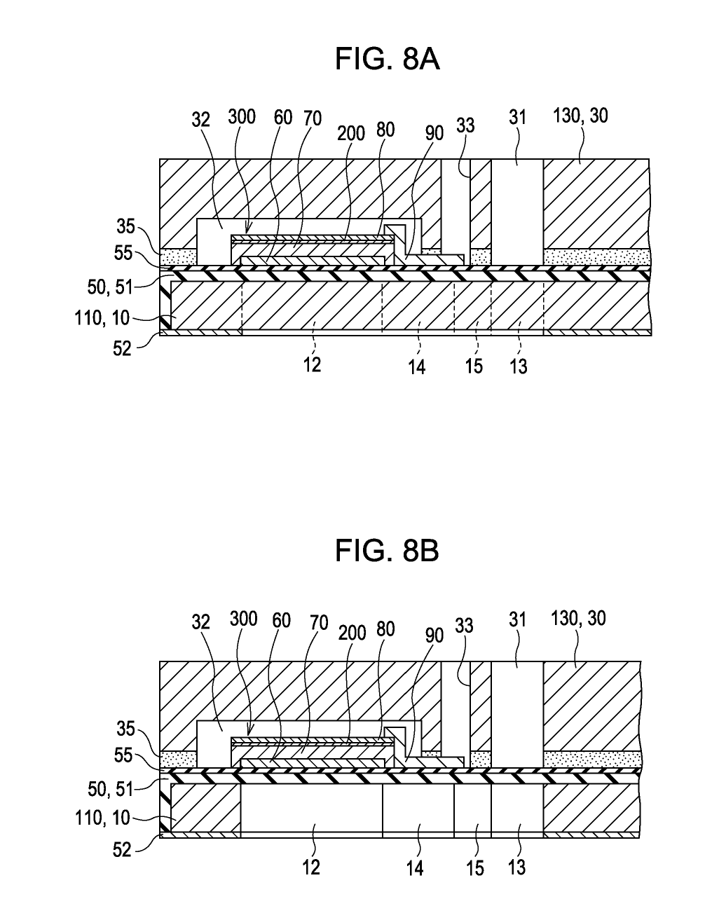

As shown in FIG. 8A, a mask film 52 is newly formed on the wafer 110 and patterned into a particular shape. As shown in FIG. 8B, the wafer 110 is anisotropically etched (wet-etched) with an alkaline solution such as KOH through the mask film 52 to form pressure-generating chambers 12, communicating sections 13, ink channels 14, communication channels 15, etc., corresponding to the piezoelectric devices 300.

Then unneeded peripheral portions of the wafers 110 and 130 are removed by, for example, dicing. A nozzle plate 20 having nozzle openings 21 is bonded onto a surface of the wafer 110 opposite the wafer 130. A compliance substrate 40 is bonded to the wafer 130. Then the wafer 110 and other associated parts are divided into channel forming substrates 10 each having a size of a chip as shown in FIG. 1 to form the ink jet recording head of this embodiment.

### EXAMPLES

An ink jet recording head I was prepared by the same method as one described above. In particular, a metal oxide film 200 having a thickness of 10 nm composed of lanthanum nickel oxide was formed by sputtering at 250° C. using an argon/oxygen mixed gas (gas flow ratio: O₂/(Ar+O₂)=50%) at a gas pressure of 1.2 Pa on a piezoelectric layer composed of lead zirconate titanate. A second layer having a thickness of 40 nm was formed by sputtering using zirconium at 250° C. and a power density of about 6 kW/m².

The ratio of lanthanum to nickel in the metal oxide film 200 was 1.489. Such a metal oxide film 200 can be formed by adjusting the mass ratio of the lanthanum and nickel target.

### Comparative Example

An ink jet recording head of Comparative Example was prepared by using the same materials and production method as in Example except for the step of forming the metal oxide film 200. In particular, a second electrode 80 composed of iridium having a thickness of 50 nm was formed on the piezoelectric layer.

### Test Example

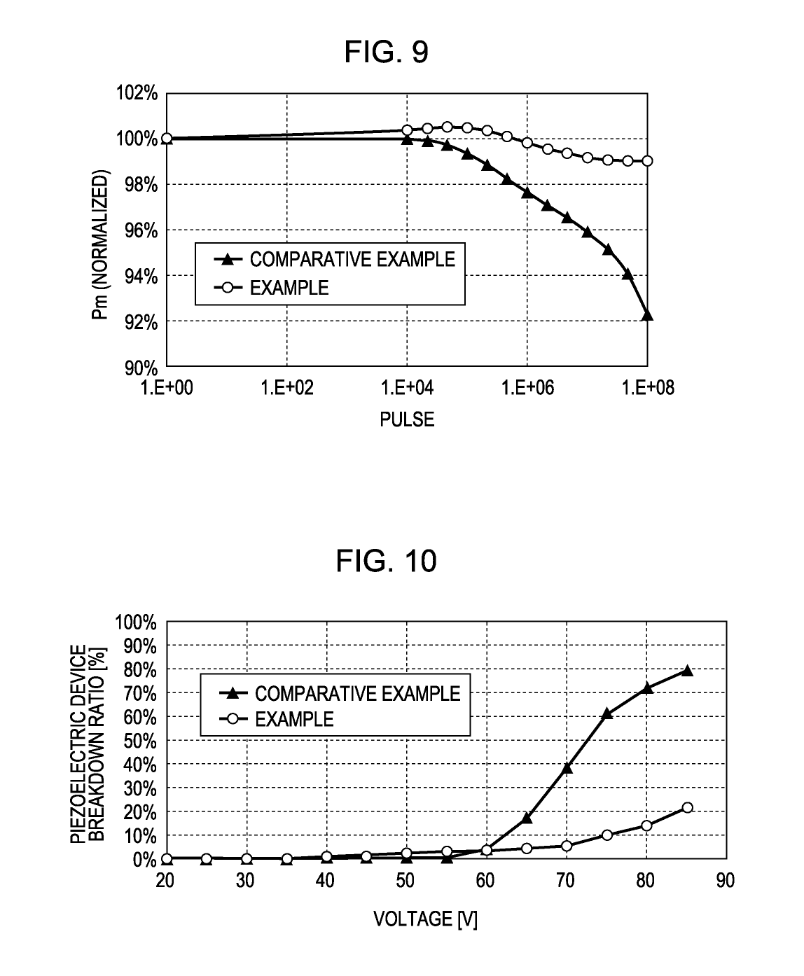

Piezoelectric devices of the ink jet recording heads of Example and Comparative Example were repeatedly driven to produce displacement. The saturation polarization (maximum polarization: Pm) of the piezoelectric device in the region not opposing the pressure-generating chambers of the ink jet recording head was measured. In this example, a square wave having a frequency of 50 kHz at a voltage of ±25 V was used as the driving waveform for repeatedly driving the piezoelectric devices. The saturation polarization (Pm) was measured by repeatedly applying a triangular wave of 66 Hz at ±35 V. The results are shown in FIG. 9. Note that the saturation polarization (Pm) was indicated as a percentage with respect to the initial state by assuming Pm of the initial state before repeated displacement to be 100%.

As shown in FIG. 9, the saturation polarization (Pm) of the piezoelectric devices of Example barely changes between the initial state and after the repeated driving and stays substantially constant. The saturation polarization of the piezoelectric devices of Example after being pulse-driven for 1.0×10⁸ times was 99.1%. In contrast, the saturation polarization of the piezoelectric devices of Comparative Example was lower than that of Example and was 92.3%.

The ratio of piezoelectric devices in which breakdown occurred when the voltage applied to the piezoelectric devices of Example and Comparative Example was gradually increased was determined. The results are shown in FIG. 10. As shown in FIG. 10, the voltage resistance is higher in Example than in Comparative Example.

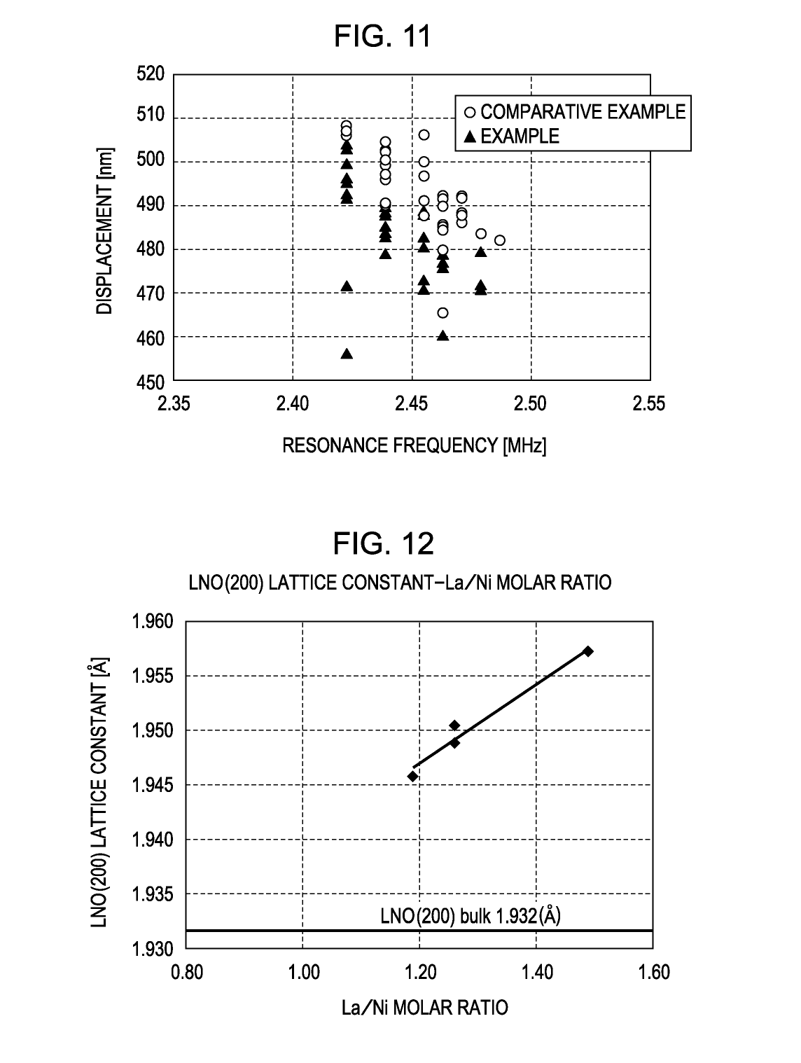

The displacement of the piezoelectric devices of each of the ink jet recording heads was also determined. The results are shown in FIG. 11. FIG. 11 is a graph showing the measured displacement of the piezoelectric devices versus the resonance frequency of the pulse driving applied to the piezoelectric devices.

As shown in FIG. 11, the piezoelectric devices of Example tend to show larger displacement than the piezoelectric devices of Comparative Example at any resonance frequency. This shows that the displacement of the piezoelectric devices of Example is larger than that of Comparative Example.

As previously described, since a metal oxide film 200 having a perovskite structure and a lanthanum/nickel molar ratio of 1.2 to 1.5 is provided between the piezoelectric layer 70 and the second electrode, the saturation polarization of the piezoelectric device 300 barely decreases by repeated driving, voltage resistance is improved, and the displacement is increased.

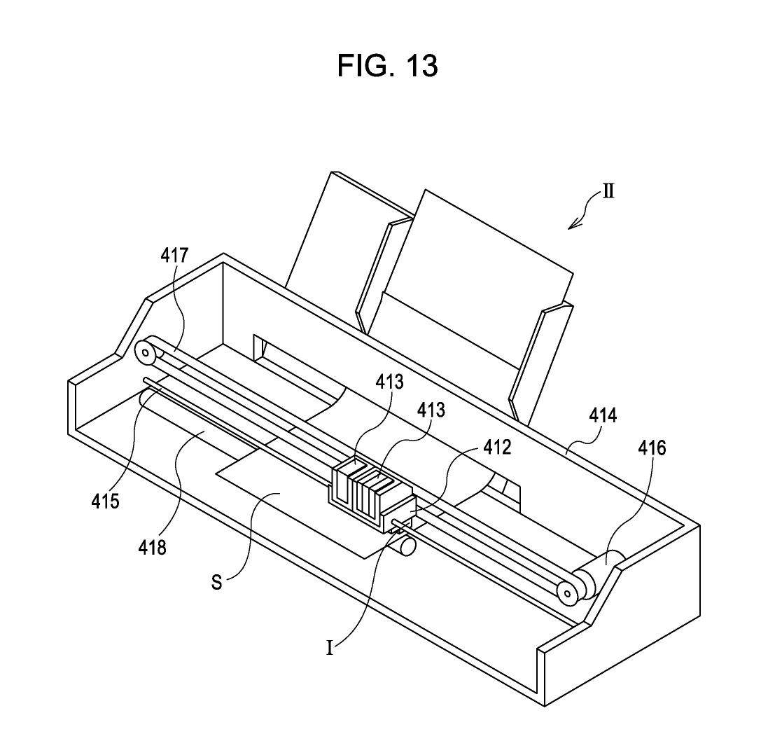

Such effects are obtained by the use of the metal oxide film 200 composed of lanthanum nickel oxide having a lanthanum molar ratio greater than the nickel molar ratio (lanthanum-rich). This is described below with reference to FIG. 12. FIG. 12 is a graph showing the relationship between the lanthanum molar ratio relative to nickel and the lattice constant of lanthanum nickel oxide.

As shown in the graph, the lattice constant increases with the lanthanum molar ratio relative to nickel. In particular, the lattice constant is 1.946 Å when the molar ratio is 1.190, 1.949 Å or 1.951 Å when the molar ratio is 1.261, and 1.957 Å when the molar ratio is 1.489.

The lattice constant of PZT (200) that forms the piezoelectric layer 70 is 2.033 Å. In other words, the larger the lanthanum molar ratio in lanthanum nickel oxide, the closer the lattice constant of lanthanum nickel oxide to the lattice constant of PZT. It can be assumed that because the metal oxide film 200 composed of the lanthanum-rich lanthanum nickel oxide enhances the lattice matching with the piezoelectric layer 70 (PZT), the piezoelectric characteristics and the voltage resistance are improved.

The piezoelectric device 300 of an embodiment and a piezoelectric device that uses a stoichiometric lanthanum nickel oxide (indicated as “LNO (200) bulk” in the graph) are compared. Bulk LNO is LNO having a perovskite structure and a lanthanum/nickel ratio of 1/1. Bulk LNO is stoichiometric.

The stoichiometric LNO has a lattice constant smaller than that of the lanthanum nickel oxide of the metal oxide film 200. In other words, the lattice matching between the metal oxide film composed of stoichiometric LNO and the piezoelectric layer 70 is not satisfactory. Accordingly, the piezoelectric device 300 of this embodiment has better piezoelectric characteristics and higher voltage resistance than when stoichiometric LNO is used.

The Young's modulus of lanthanum is 38.4 GPa whereas the Young's modulus of nickel is 205 GPa. It can thus be assumed that lanthanum-rich lanthanum nickel oxide has a lower Young's modulus, is easily flexible, and significantly improves the displacement characteristics.

### Other Embodiments

Although the invention has been described through the embodiment above, the basic features of the invention are not limited to those described above. For example, in the embodiment, a silicon single crystal substrate has been described as an example of the channel forming substrate 10. However, the substrate is not limited to this and a silicon-on-insulator (SOI) substrate, a glass substrate, or the like may be used.

The ink jet recording heads produced in the embodiments are mounted to ink jet recording apparatuses so as to form a part of a recording head unit including ink channels in communication with ink cartridges etc. FIG. 13 is a schematic view showing an example of the ink jet recording apparatus.

As shown in FIG. 13, an ink jet recording apparatus II includes an ink jet recording head (referred to as “recording head” hereinafter) I that ejects ink droplets and fixed on a carriage 412. Ink cartridges 413 which are liquid-storing units that store inks of different colors, e.g., black (B), cyan (C), magenta (M), and yellow (Y) are detachably mounted on the carriage 412. The ink cartridges 413 are configured to supply inks to the recording head I so that the recording head I can eject inks.

The carriage 412 on which the recording head I is mounted is attached to a carriage shaft 415 of an apparatus main body 414 so that the carriage 412 can freely move along the shaft. The driving force of a driving motor 416 is transmitted to the carriage 412 via a plurality of gears (not shown) and a timing belt 417 so that the carriage 412 moves along the carriage shaft 415. A platen 418 is installed in the apparatus main body 414 along the carriage shaft 415 so that a recording medium S such as paper fed from a paper feeder (not shown) can be transferred onto the platen 418.

According to the ink jet recording apparatus II described above, the ink jet recording head I is mounted onto the carriage 412 and moved in the main scanning direction. However, the recording apparatus is not limited to this, and the invention encompasses a line-type recording apparatus that includes an ink jet recording head I that is fixed and performs printing by moving the recording medium S such as paper in the sub scanning direction.

In the first embodiment described above, an ink jet recording head is used as an example of a liquid ejecting head. However, the invention encompasses all types of liquid ejecting heads and can naturally applied to liquid ejecting heads that eject liquid other than inks. Examples of other liquid ejecting heads include various types of recording heads used in image-recording apparatuses such as printers, coloring material ejecting heads used in producing color filters of liquid crystal displays and the like, electrode material ejecting heads used in forming electrodes of organic electroluminescence (EL) displays, field-emission displays (FEDs), etc., and biological organic matter-ejecting heads used in making biochips.

What is claimed is:

1. A piezoelectric device comprising:
a first electrode;
a piezoelectric layer above the first electrode;
a metal oxide film above the piezoelectric layer; and
a second electrode above the metal oxide film,
wherein the metal oxide film is including a lanthanum nickel oxide having a perovskite structure and a lanthanum/nickel molar ratio of 1.2 to 1.5.

2. The piezoelectric device according to claim 1, wherein the metal oxide film has a thickness of 1 nm or more.

3. The piezoelectric device according to claim 1, wherein the first electrode is including platinum or iridium.

4. A liquid ejecting head comprising the piezoelectric device according to claim 1.

5. A liquid ejecting apparatus comprising the liquid ejecting head according to claim 4.
